(19) United States
(12) Patent Application Publication
(10) Pub. No.: US 2026/0013046 A1
(43) Pub. Date: Jan. 8, 2026

(54) PRINTED CIRCUIT ASSEMBLY AND METHOD OF MANUFACTURING ELECTRONIC APPARATUS BY USING THE SAME

(71) Applicant: SAMSUNG DISPLAY CO., LTD., Yongin-si (KR)

(72) Inventors: Huntae Kim, Yongin-si (KR); Sanghyeok Kim, Yongin-si (KR); Sungsu Kim, Yongin-si (KR); Ilwoo Park, Yongin-si (KR); Taewoung Byun, Yongin-si (KR)

(21) Appl. No.: 19/171,489

(22) Filed: Apr. 7, 2025

(30) Foreign Application Priority Data
Jul. 3, 2024 (KR) 10-2024-0087804

(51) Int. Cl. H05K 1/14

(52) U.S. Cl. CPC H05K 1/144; H05K 2201/041; H05K 2201/09027; H05K 2201/10128

(57) ABSTRACT

A printed circuit assembly includes a first support, a first circuit board overlapping a first area of the first support and attached to a first surface of the first support, a second circuit board overlapping a second area of the first support and attached to the first surface of the first support, and a second support overlapping the first area and the second area of the first support and attached to a second surface of the first support.

### CROSS-REFERENCE TO RELATED APPLICATION

This application is based on and claims priority under 35 U.S.C. § 119 to Korean Patent Application No. 10-2024-0087804, filed on Jul. 3, 2024, in the Korean Intellectual Property Office, the disclosure of which is incorporated by reference herein in its entirety.

### BACKGROUND

### 1. Technical Field

One or more embodiments relate to a printed circuit assembly and a method of manufacturing an electronic apparatus by using the same.

### 2. Discussion of Related Art

An electronic apparatus may include display apparatuses to generate visual information, such as images or video, which may be perceived by a user. Display apparatuses may include a substrate partitioned into a display area and a peripheral area. In the display area, a scan line and a data line may be insulated from each other, and a plurality of pixels may be provided. In addition, thin-film transistors and pixel electrodes electrically connected to the thin-film transistors may be provided in the display area to correspond to each of the pixels. In addition, opposite electrodes commonly provided for the pixels may be provided in the display area. Various wires configured to transmit electrical signals to the display area may be provided in the peripheral area. These wires may include, a scan driver, a data driver, a controller, a pad portion, and the like.

Display apparatuses may include a circuit board for transmitting electrical signals, for example, a printed circuit board (PCB). Various electronic parts may be mounted on the PCB. The PCB may be a flexible printed circuit board (FPCB) (hereinafter, a flexible circuit board), which may be partially bendable. In some cases, a portion of the flexible circuit board may be bent and positioned under another portion.

### SUMMARY

According to one or more embodiments, a printed circuit assembly includes a first support, a first circuit board overlapping a first area of the first support and attached to a first surface of the first support, a second circuit board overlapping a second area of the first support and attached to the first surface of the first support, and a second support overlapping the first area and the second area of the first support and attached to a second surface of the first support.

According to an embodiment, an area of the second support may be smaller than an area of the first support, and the entirety of the second support may overlap the first support.

According to an embodiment, the first support may include a first periphery defining an outer edge portion of the first support and a second periphery defining an inner edge of an opening overlapping the first circuit board.

According to an embodiment, the second circuit board may include a connector positioned outside a first periphery of the first support.

According to an embodiment, the second support may overlap a 2nd-1 area of the second area of the first support, wherein the 2nd-1 area may be adjacent to the connector.

According to an embodiment, the first circuit board and the second circuit board may be connected to each other.

According to an embodiment, the first circuit board and the second circuit board may be connected to each other and overlap each other outside a periphery of the first support and a periphery of the second support.

According to an embodiment, the first circuit board and the second circuit board may be connected to each other, a first surface of the first circuit board is in contact with the first support and a first surface of the second circuit board, and a second surface of the second circuit board opposite to the first surface of the second circuit board is in contact with the first support.

According to an embodiment, the first support may have a projecting portion in the second area and the second support may overlap the projecting portion of the first support in the second area.

According to an embodiment, the second circuit board may include a connector extending from the projecting portion and positioned outside a first periphery of the first support.

According to an embodiment, the second support may support the projecting portion of the first support in the second area.

According to one or more embodiments, a method of manufacturing an electronic apparatus include preparing a display apparatus and attaching the display apparatus to a housing, wherein preparing the display apparatus includes forming a printed circuit assembly, wherein forming the printed circuit assembly includes providing a first support and a second support overlapping a first area of the first support and a second area of the first support, positioning a first circuit board overlapping the first area of the first support and attached to a first surface of the first support, and positioning a second circuit board overlapping the second area of the first support and attached to the first surface of the first support, picking up the printed circuit assembly, and attaching the printed circuit assembly to a display substrate, wherein the second support is attached to a second surface of the first support opposite the first surface of the first support.

According to an embodiment, an area of the second support may be smaller than an area of the first support, and the entirety of the second support may overlap the first support, wherein picking up the printed circuit assembly comprises coupling a picker to the second support.

According to an embodiment, the first support may include a first periphery defining an outer edge portion of the first support and a second periphery defining an inner edge of an opening overlapping the first circuit board, wherein picking up the printed circuit assembly comprises coupling a picker to a portion of the second support adjacent to the opening.

According to an embodiment, the second circuit board may include a connector positioned outside the first support.

According to an embodiment, the second support may be positioned to overlap a 2nd-1 area of the second area of the first support, wherein the 2nd-1 area may be adjacent to the connector.

According to an embodiment, the first circuit board and the second circuit board may be bonded together.

According to an embodiment, the first circuit board and the second circuit board may be positioned to overlap each other outside the first support and the second support.

According to an embodiment, the first circuit board and the second circuit board may be positioned such that a first surface of the first circuit board may be in contact with the first support and a first surface of the second circuit board, and a second surface of the second circuit board opposite to the first surface of the second circuit board may be in contact with the first support.

According to an embodiment, the picking up may include coupling a picker to the second support in the first area.

According to an embodiment, the attaching may include positioning the first circuit board and the second circuit board to face the display substrate.

According to an embodiment, the method may further include separating the first support and the second support from the first circuit board and the second circuit board, wherein the first circuit board and the second circuit board may remain attached to the display substrate.

According to an embodiment, the method may further include bending a portion of the second circuit board.

### BRIEF DESCRIPTION OF THE DRAWINGS

Aspects, features, and advantages of embodiments of the disclosure will be more apparent from the following description taken in conjunction with the accompanying drawings, in which:

FIG. 1 is a plan perspective view of a printed circuit assembly according to an embodiment;

FIG. 2 is a plan exploded view of a printed circuit assembly according to an embodiment;

FIG. 3 is a cross-sectional view of a printed circuit assembly according to an embodiment, taken along a line III-III′ of FIG. 1;

FIG. 4 is a cross-sectional view of a printed circuit assembly according to an embodiment, taken along a line IV-IV′ of FIG. 1;

FIG. 5 is a plan view schematically showing operations of a process of a method of manufacturing a display apparatus, according to an embodiment;

FIGS. 6 to 10 are cross-sectional views schematically showing operations of a process of a method of manufacturing a display apparatus, according to an embodiment; and

FIG. 11 is a flow diagram of a method of manufacturing an electronic apparatus according to an embodiment.

### DETAILED DESCRIPTION

Reference will now be made in detail to embodiments, examples of which are illustrated in the accompanying drawings. Like reference numerals refer to like elements throughout. In this regard, embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, embodiments may have different forms and should not be construed as being limited to the descriptions set forth herein.

One or more embodiments will be described below in more detail with reference to the accompanying drawings. Components may be identified by the same reference numeral in the drawings, and redundant descriptions thereof may be omitted.

While such terms as “first” and “second” may be used to describe various elements, such elements may not be limited to these terms. These terms may be used to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, sizes and thicknesses of elements in the drawings may be arbitrarily illustrated for convenience of description, and the following embodiments are not limited thereto.

When an embodiment may be implemented differently, a certain process order may be performed differently from a described order. For example, two consecutively described processes may be performed substantially at the same time or performed in an order opposite to the described order.

As used herein, the expression “A and/or B” refers to A, B, or A and B. In addition, the expression “at least one of A or B” refers to A, B, or A and B.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

In an embodiment, a flexible circuit board may be included in a display apparatus by being separately prepared and attached to a display panel. Before being attached to the display panel, the flexible circuit board may be attached to a support. The support may support the flexible circuit board, and may inhibit or prevent premature contact between the flexible circuit board and the display panel. The support may have a flat surface and may maintain the flexible circuit board flat during attachment of the flexible circuit board to the display panel. After the flexible circuit board is attached to the display panel, the support may be removed from the flexible circuit board.

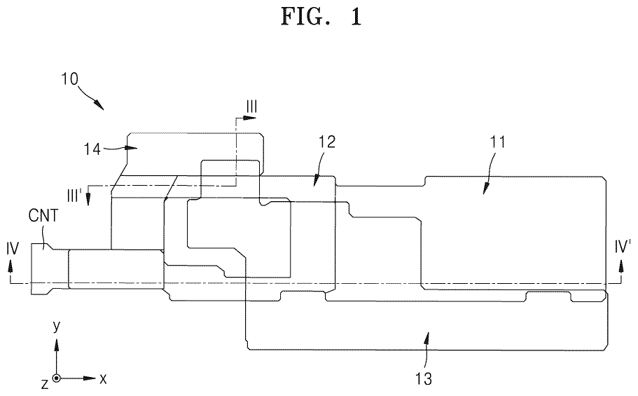

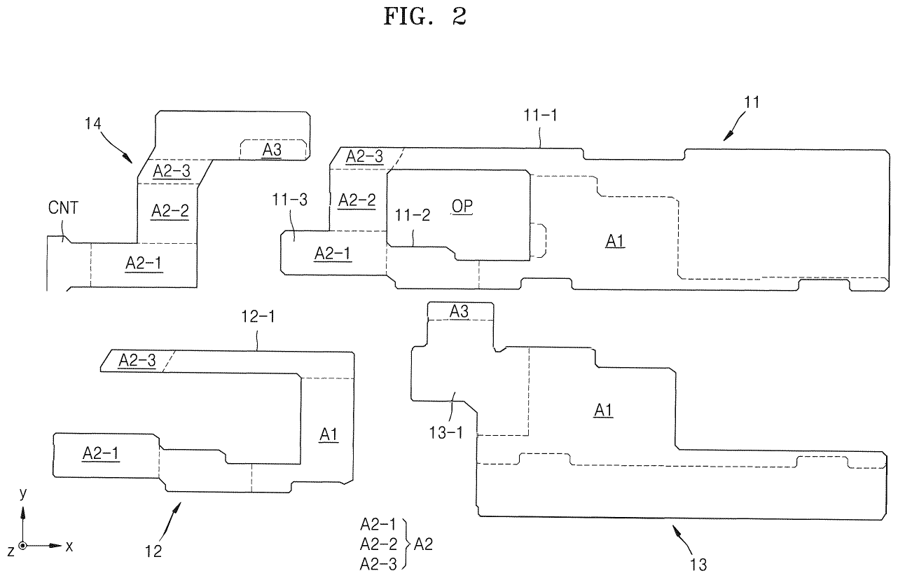

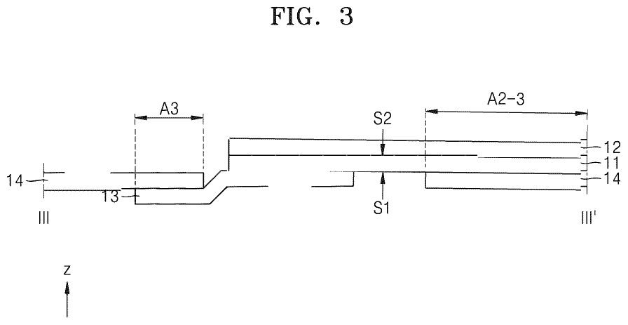

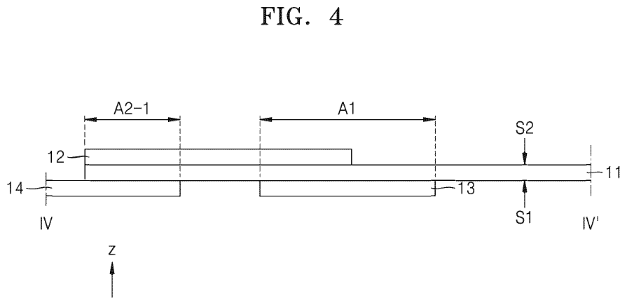

FIG. 1 is a plan perspective view of a printed circuit assembly 10 according to an embodiment. FIG. 2 is a plan exploded view of the printed circuit assembly 10 according to an embodiment. FIG. 3 is a cross-sectional view of the printed circuit assembly 10 according to an embodiment, taken along a line III-III′ of FIG. 1. FIG. 4 is a cross-sectional view of the printed circuit assembly 10 according to an embodiment, taken along a line IV-IV′ of FIG. 1.

Referring to FIGS. 1 to 4 together, the printed circuit assembly 10 may include a first support 11, a second support 12, a first circuit board 13, and a second circuit board 14. In an embodiment, at least one of the first support 11 or the second support 12 may include a release liner, such as a release paper or a release film.

As shown in FIG. 1, the first support 11, the second support 12, the first circuit board 13, and the second circuit board 14 may be assembled to partially overlap each another and may be included in the printed circuit assembly 10. In an embodiment, portions of the first support 11, the second support 12, the first circuit board 13, and the second circuit board 14 may be adhered to other portions thereof. For example, the first circuit board 13 and the second circuit board 14 may be attached to the first support 11. From another perspective, the first support 11 may be attached to the first circuit board 13 and the second circuit board 14.

In an embodiment, at least some of the first support 11, the second support 12, the first circuit board 13, or the second circuit board 14 may be separably connected to each other. In an embodiment, the first support 11 and the first circuit board 13 may be separably connected to each other. In an embodiment, the first support 11 and the second circuit board 14 may be separably connected to each other. For example, the first support 11 and the second support 12 may be bonded to each other, the first circuit board 13 and the second circuit board 14 may be bonded to each other, and the first circuit board 13 and the second circuit board 14 may be separably bonded to the first support 11. In an embodiment, the first support 11 and the second support 12 may be separably bonded or permanently bonded to each other. In an embodiment, the first circuit board 13 and the second circuit board 14 may be positioned relative to one another while bonded to the first support 11, but may not be bonded directed to each other. In an embodiment, bonding may be variously achieved. For example, the bonding may be achieved by solder or an adhesive.

FIG. 2 is a plan exploded view of the printed circuit assembly 10 in which each portion is separated from each another. Areas where the first support 11, the second support 12, the first circuit board 13, or the second circuit board 14 overlap each other are marked using the same reference numerals.

Areas of the first support 11, the second support 12, the first circuit board 13, or the second circuit board 14 that overlap may have the same shape and size or different shapes and sizes depending on overlapping portions thereof. For example, an area of the second support 12 may be smaller than an area of the first support 11 and an entirety of the second support 12 may overlap the first support 11.

In an embodiment, an area where the first support 11 and the first circuit board 13 overlap each other may be defined as a first area A1. In other words, the first area A1 of the first circuit board 13 may overlap the first area A1 of the first support 11. In other words, the first area A1 of the first support 11 may overlap the first area A1 of the first circuit board 13. In an embodiment, the first area A1 of the second support 12 may also overlap the first areas A1 the first support 11 and the first circuit board 13. The first areas A1 of the first support 11, the second support 12, and the first circuit board 13 that overlap may have the same shape and size or different shapes and sizes depending on overlapping portions thereof.

In an embodiment, an area where the first support 11 and the second circuit board 14 overlap each other may be defined as a second area A2. In other words, the second area A2 of the second circuit board 14 may overlap the second area A2 of the first support 11. In other words, the second area A2 of the first support 11 may overlap the second area A2 of the second circuit board 14. The second areas A2 of the first support 11 and the second circuit board 14 that overlap may have the same shape and size or different shapes and sizes depending on overlapping portions thereof.

In an embodiment, the second area A2 may include portions including a 2nd-1 area A2-1, a 2nd-2 area A2-2, and a 2nd-3 area A2-3. In a plan view, the 2nd-1 area A2-1 and the 2nd-2 area A2-2 may adjoin each other, and the 2nd-2 area A2-2 and the 2nd-3 area A2-3 may adjoin each other, wherein the 2nd-2 area A2-2 may be disposed between the 2nd-1 area A2-1 and the 2nd-3 area A2-3. For example, the second area A2 may be a contiguous area, and different ones of the first support 11, the second support 12, and the second circuit board 14 may overlap different portions of the second area A2.

In an embodiment, portions of the second support 12 may also overlap portions of the second area A2. In an embodiment, in the second area A2, areas where the first support 11, the second support 12, and the second circuit board 14 overlap one another may be defined as the 2nd-1 area A2-land the 2nd-3 area A2-3. The 2nd-1 area A2-1 and the 2nd-3 area A2-3 may be spaced apart from each other. In an embodiment, the 2nd-3 area A2-3 may be positioned in a +y direction relative to the 2nd-1 area A2-1.

In an embodiment, a portion of the second area A2 that overlaps the first support 11 and the second circuit board 14 may be defined as the 2nd-2 area A2-2. In an embodiment, the 2nd-2 area A2-2 may be disposed between the 2nd-1 area A2-1 and the area A2-3. The second support 12 may include an open portion disposed to overlap the 2nd-2 area A2-2. In an embodiment, the open portion of the second support 12 may coincide with the 2nd-2 area A2-2 of the first support 11 and the second circuit board 14, and the second support 12 may not overlap the 2nd-2 area A2-2 of the first support 11 and the second circuit board 14.

In an embodiment, an area where the first circuit board 13 and the second circuit board 14 overlap each other may be defined as a third area A3. In an embodiment, as shown in FIG. 3, the third area A3 may be positioned beyond edges of the first support 11 and the second support 12. In other words, the third area A3 may be positioned outside a periphery of the first support 11 and the second support 12. In an embodiment, the first circuit board 13 and the second circuit board 14 may be electrically connected to each other in the third area A3. In an embodiment, the first circuit board 13 and the second circuit board 14 may be in contact with each other and electrically connected to each other in the third area A3.

In an embodiment, the 2nd-1 area A2-1 of the first support 11 may be a projecting portion 11-3. The projecting portion 11-3 may extending in an −x direction from the first support 11. The second support 12 may overlap the projecting portion 11-3 of the first support 11 in the 2nd-1 area A2-1. The second circuit board 14 may include a connector CNT. In an embodiment, the connector CNT may be disposed adjacent to the 2nd-1 area A2-1. In an embodiment, the second circuit board 14 may include the 2nd-2 area A2-2 adjoining the 2nd-1 area A2-1, and the connector CNT spaced apart from the 2nd-2 area A2-2 and adjoining the 2nd-1 area A2-1. The connector CNT may extend from the projecting portion 11-3 of the first support 11 and may be positioned outside the first periphery 11-1 of the first support 11.

In an embodiment, the connector CNT may be a portion that connects to another element of a display apparatus when the second circuit board 14 is embedded in the display apparatus and electrically connects the second circuit board 14 to the element of the display apparatus.

Referring to FIG. 1, the second circuit board 14, and more particularly, the connector CNT of the second circuit board 14, may be positioned at an end portion (e.g., a −x direction end portion) of the printed circuit assembly 10. The second support 12 may overlap a relative center portion of the printed circuit assembly 10, for example, a +x direction portion of an opening OP of the first support 11, and may extend in a −x direction and overlap the second circuit board 14 in the 2nd-1 area A2-1 and the 2nd-3 area A2-3. In this case, the second support 12 may secure the second circuit board 14. Accordingly, the second support 12 may inhibit or prevent sagging of the first support 11. For example, the second support 12 may inhibit or prevent sagging of the first support 11 due to the weight of the second circuit board 14 relatively positioned at an end portion of the printed circuit assembly 10. That is, the second support 12 may provide increased structural rigidity to the first support 11. The second support 12 may provide increased structural rigidity to the printed circuit assembly 10. In an embodiment, the second support 12 may be smaller than the first support 11, and the second support 12 may be arranged to provide structural rigidity to the first support 11. In addition, in an embodiment, the second support 12 may overlap the first support 11. In an embodiment, an entirety of the second support 12 may overlap the first support 11.

In an embodiment, the first support 11 may include the opening OP overlapping a portion of the first circuit board 13. A portion of the first circuit board 13 may be exposed through the opening OP of the first support 11. A portion of the first circuit board 13 exposed through the opening OP of the first support 11 may be referred to as an exposed portion 13-1. A portion of an electronic part (not shown) mounted on the first circuit board 13 may be exposed through the opening OP of the first support 11. In an embodiment, the second support 12 may partially surround the opening OP of the first support 11. In an embodiment, a portion the second support 12 may have a shape that is the same as a shape of a portion of the opening OP in one direction (e.g., the −x direction).

In the present description, vertical relationships between the first support 11, the second support 12, the first circuit board 13, and the second circuit board 14 may be described with respect to the z-axis. For example, when the second support 12 is referred to as being disposed on the first support 11, the second support 12 may be positioned in a +z direction relative to the first support 11. Alternatively, when the first circuit board 13 is referred to as being disposed under the first support 11, the first circuit board 13 may be positioned in a −z direction relative to the first support 11. However, this is merely for convenience, and the printed circuit assembly 10 may be turned over during a process of manufacturing a display apparatus, and vertical relationships between the first support 11, the second support 12, the first circuit board 13, and the second circuit board 14 may be reversed.

In an embodiment, the first support 11 may include a first periphery 11-1 and a second periphery 11-2. The first periphery 11-1 may define an outer edge portion of the first support 11. The second periphery 11-2 may define an inner edge of the opening OP. For example, the second periphery 11-2 may be disposed within the first periphery 11-1. The second support 12 may include a third periphery 12-1. The third periphery 12-1 may define an outer edge portion of the second support 12. Portions of the third periphery 12-1 of the second support 12 may overlap with portions of the first periphery 11-1 and the second periphery 11-2 of the first support 11. Portions of the third periphery 12-1 of the second support 12 may overlap with an inner portion of the first support 11 in at least the first area A1 and the second area A2.

Referring to FIG. 3 and FIG. 4 together, the first circuit board 13 and the second circuit board 14 may be disposed under the first support 11. In other words, the first circuit board 13 and the second circuit board 14 may be positioned in the −z direction relative to the first support 11. In an embodiment, the first support 11 may include a first surface S1 facing the −z direction, and portions of the first circuit board 13 and the second circuit board 14 may be disposed on the first surface S1 of the first support 11. In an embodiment, the first circuit board 13 and the second circuit board 14 may be attached to the first support 11.

The second support 12 may be disposed on the first support 11. In other words, the second support 12 may be positioned in the +z direction relative to the first support 11. In an embodiment, the first support 11 may include a second surface S2 facing the +z direction and opposite the first surface S1. The second support 12 may be disposed on the second surface S2 of the first support 11. In an embodiment, the first support 11 and the second support 12 may adhere to each other.

In an embodiment, the first support 11, the second support 12, and the second circuit board 14 may overlap one another in the 2nd-1 area A2-1 and the 2nd-3 area A2-3. In an embodiment, the first support 11, the second support 12, and the first circuit board 13 may overlap one another in one or more portions of the first area A1. In an embodiment, a portion of the second circuit board 14 may not overlap the first support 11, and may not be in contact with the first surface S1 of the first support 11. For example, a portion of the second circuit board 14 that is in the third area A3 may not be in contact with the first surface S1 of the first support 11 and may not overlap the first support 11. For example, the second circuit board 14 and the first support 11 may be spaced apart in a horizontal direction, perpendicular to the z direction.

In an embodiment, a portion of the first circuit board 13 may be disposed under the second circuit board 14. For example, in the third area A3 where the first circuit board 13 and the second circuit board 14 overlap each other, the first circuit board 13 may be positioned in the −z direction relative to the second circuit board 14. In an embodiment, in the third area A3, the first circuit board 13 may be disposed under the second circuit board 14 and may connect to, and be connected to, the second circuit board 14. In an embodiment, a portion of the first circuit board 13 may be bent and in contact with the first surface S1 of the first support 11. In an embodiment, the surface of the first circuit board 13 that is in contact with the first support 11 and the surface of the first circuit board 13 that is in contact with the second circuit board 14 in the third area A3 may be connected by a bent surface of the first circuit board 13.

In an embodiment, a lower surface of the second circuit board 14 in the third area A3 may be in contact a surface of the first circuit board 13 that is in contact with the first support 11, and an upper surface of the second circuit board 14 may be in contact with the first support 11 in the 2nd-1 area A2-1. The lower surface and the upper surface of the second circuit board 14 may be disposed opposite each other in the z direction.

In an embodiment, at least one of the first support 11 or the second support 12 may include a release liner. The release liner may be a release paper or a release film. The release liner may be a single-sided release material or a double-sided release liner. The release liner may include a release agent, which may provide a release effect against at least one or a support or a circuit board. In an embodiment, the release liner may be disposed on the first surface S1 of the first support 11. For example, the release liner may be disposed between the first support 11 and at least one of the first circuit board 13 and the second circuit board 14, wherein the release liner may facilitate separation of the first support 11 and at least one of the first circuit board 13 and the second circuit board 14.

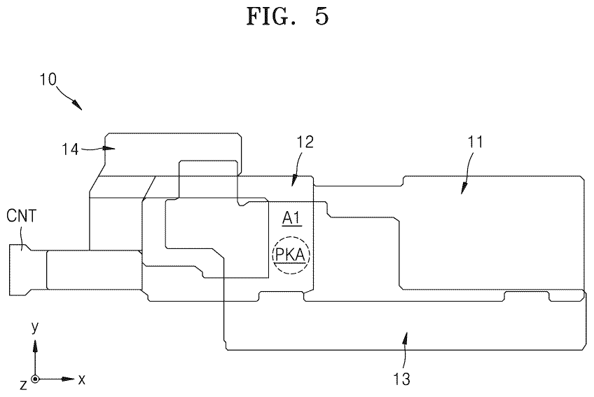

FIG. 5 is a plan view schematically showing operations of a process of a method of manufacturing a display apparatus, according to an embodiment.

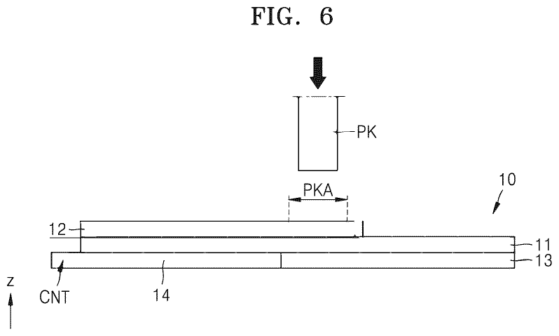

FIGS. 6 to 10 are cross-sectional views schematically showing operations of a portion of a method of manufacturing a display apparatus, according to an embodiment.

FIG. 5 and FIG. 6 may be a plan view and a cross-sectional view showing a portion of a method of manufacturing a display apparatus.

Referring to FIG. 5 and FIG. 6 together, a picker PK may be aligned with the printed circuit assembly 10 to pick up the printed circuit assembly 10. In an embodiment, the picker PK may be aligned with a picking area PKA of the printed circuit assembly 10. In an embodiment, the picking area PKA may be positioned within the first area A1. In an embodiment, the picking area PKA may be positioned within the first area A1 and on a portion the second support 12 adjacent to the opening OP. The picker PK may include any suitable element(s) capable of picking up the printed circuit assembly 10 while in contact with the printed circuit assembly 10. For example, the picker PK may use vacuum nozzles or mechanical grips to selective secure the printed circuit assembly 10.

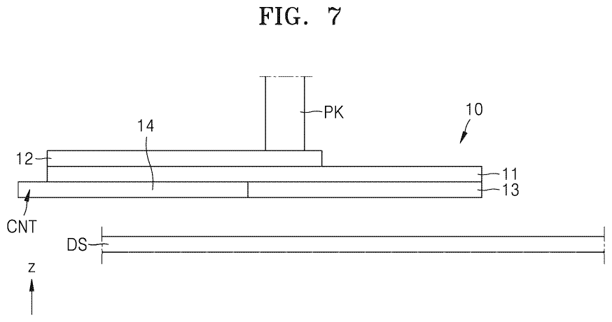

Referring to FIG. 7, after alignment is completed, the picker PK may be lowered to couple the picker PK and the printed circuit assembly 10 to each other. In an embodiment, the picker PK and the printed circuit assembly 10 may be coupled to each other while in direct contact with each other. In an embodiment, the picker PK and the second support 12 may be in direct contact with each other. In an embodiment, the picker PK may be in direct contact with an upper surface (e.g., a +z direction surface) of the second support 12.

After coupling, the printed circuit assembly 10 coupled to the picker PK may be aligned with a display substrate DS. The display substrate DS may be a semi-finished product at a stage in a process of manufacturing a display panel including a display apparatus. In an embodiment, the display substrate DS may have a conductive layer, an insulating layer, and a semiconductor layer formed on a substrate over an area or in a pattern.

In an embodiment, the printed circuit assembly 10 coupled to the picker PK may be moved by moving the picker PK. In an embodiment, the printed circuit assembly 10 and the display substrate DS may be aligned with each other by using an alignment mark on at least one of the printed circuit assembly 10 or the display substrate DS. In an embodiment, the printed circuit assembly 10 may be aligned with the display substrate DS such that the first circuit board 13 and the second circuit board 14 face the display substrate DS.

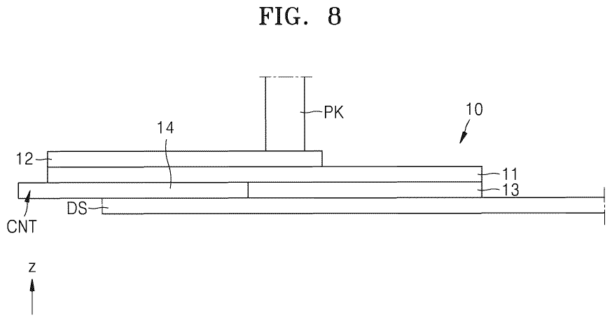

Referring to FIG. 8, the printed circuit assembly 10 and the display substrate DS may be brought into contact with each other and coupled to each other. In an embodiment, portions of the first circuit board 13 and the second circuit board 14 may be in contact with and coupled to the display substrate DS. In an embodiment, coupling between the first circuit board 13 and the display substrate DS may be performed through pressing. In an embodiment, coupling between the second circuit board 14 and the display substrate DS may be performed through pressing.

In an embodiment, the first circuit board 13 and the second circuit board 14 may be flexible printed circuit boards (FPCBs). In this case, the first circuit board 13 and the second circuit board 14 may be coupled to the first support 11 having a flat surface and the first circuit board 13 and the second circuit board 14 may come into contact with the display substrate DS while in a flat state. For example, lower surfaces of the first circuit board 13 and the second circuit board 14 may be colinear.

In an embodiment, the connector CNT of the second circuit board 14 may be positioned at an end portion of the printed circuit assembly 10. In other words, the connector CNT of the second circuit board 14 may be a portion of the printed circuit assembly 10 furthest away from the picker PK and the picking area PKA. With respect to the picker PK, a moment arm at the connector CNT may be greater than a moment arm near the picker PK and the picking area PKA. Accordingly, a torque due to gravity at the connector CNT may be greater than a torque due to gravity near the picker PK and the picking area PKA.

In an embodiment, a direction of gravity may be a −z direction. Accordingly, in an embodiment, the connector CNT may sag in a direction (e.g., the −z direction) of gravity. In this case, a portion of the connector CNT that has sagged may be in contact with a portion of equipment where a process of manufacturing a display apparatus is performed and/or the display substrate DS. As described herein, a combined structural rigidity of the second support 12 and the first support 11 may provide improved support. Accordingly, during a process of manufacturing a display apparatus in which the second support 12 is present, the connector CNT may not sag despite the torque due to gravity.

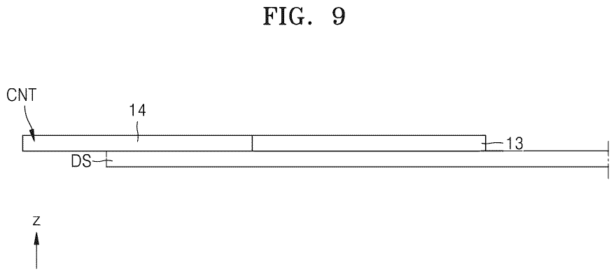

Referring to FIG. 8 and FIG. 9 together, the first support 11 may be separated from the first circuit board 13 and the second circuit board 14. As described herein, the first support 11 may include a release paper or a release film, and the first support 11 may be attached to the first circuit board 13 and the second circuit board 14 in a separable state. The first support 11 may provide a flat surface to the first circuit board 13 and the second circuit board 14 and may allow coupling with the display substrate DS. Accordingly, after the first circuit board 13 and the second circuit board 14 are coupled to the display substrate DS, the first support 11 may be separated from an assembly of the first circuit board 13, the second circuit board 14, and the display substrate DS. In an embodiment, the second support 12 coupled to the first support 11 may also be removed together with the first support 11.

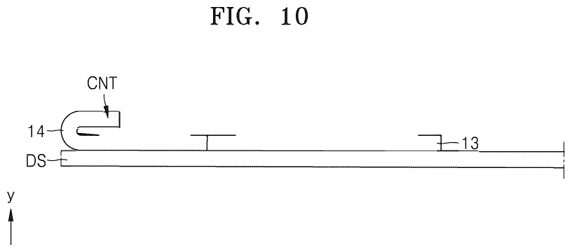

Referring to FIG. 10, a portion of the second circuit board 14 may be bent. For example, an end portion of the second circuit board 14 may be bent to be positioned over another portion of the second circuit board 14. In an embodiment, a portion of the second circuit board 14 that includes the connector CNT may be bent. In an embodiment, the connector CNT may be positioned over another portion of the second circuit board 14. However, this is for convenience of description, and when viewed based on a display apparatus, the first circuit board 13 and the second circuit board 14 may be construed as being positioned under the display substrate DS, and the connector CNT may be construed as being positioned bent to have a level that is lower than that of another portion of the second circuit board 14.

According to some embodiments, a first circuit board and a second circuit board (at least one of which may be a flexible circuit board) may be attached to a first support described herein, and a second support may be attached thereto to additionally provide structural rigidity to the first support. The first support additionally provided with structural rigidity of the second support may not have an end portion thereof, such as the projecting portion 11-3, sagging despite the weight of the first circuit board, the weight of the second circuit board, and/or the weight of the first support itself. Accordingly, a phenomenon in which an end portion of a printed circuit assembly sags and comes into contact with equipment during the process may be inhibited or prevented.

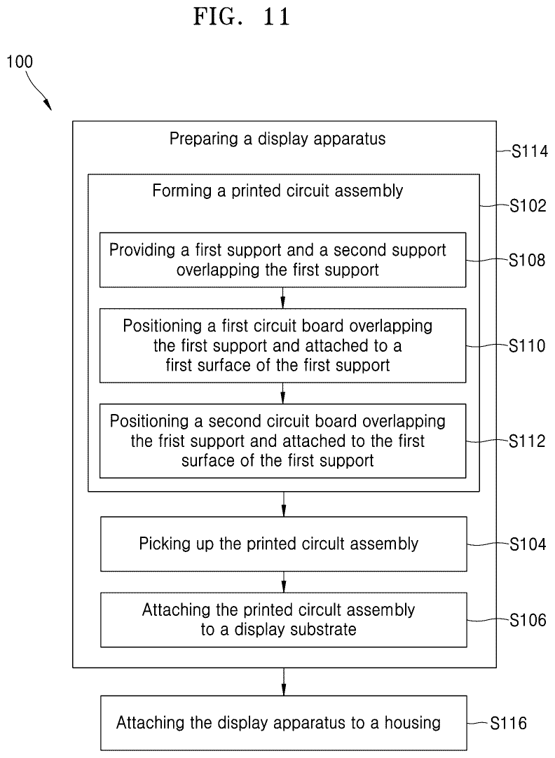

Referring to FIG. 11, a method 100 of manufacturing an electronic apparatus may include preparing a display apparatus at step S114 and attaching the display apparatus to a housing at step S116. Preparing the display apparatus at step S114 may include forming a printed circuit assembly at step S102 picking up a printed circuit assembly at step S104, and attaching the printed circuit assembly to a display substrate at step S106.

In an embodiment, forming the printed circuit assembly at step S102 may include providing a first support and a second support overlapping a first area of the first support and a second area of the first support at step S108, positioning a first circuit board overlapping the first area of the first support and attached to a first surface of the first support at step S110, positioning a second circuit board overlapping the second area of the first support and attached to the first surface of the first support at step S112.

The providing of the first support and a second support overlapping a first area of the first support and a second area of the first support at step S108 may include attaching the second support to a second surface of the first support opposite the first surface of the first support.

In an embodiment, attaching the printed circuit assembly to a display substrate at step S106 may include a step of bending the connector CNT, for example, to have a level that is higher than that of another portion of the second circuit board.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A printed circuit assembly comprising:
a first support;
a first circuit board overlapping a first area of the first support and attached to a first surface of the first support;
a second circuit board overlapping a second area of the first support and attached to the first surface of the first support; and
a second support overlapping the first area and the second area of the first support and attached to a second surface of the first support.

2. The printed circuit assembly of claim 1, wherein an area of the second support is smaller than an area of the first support, and an entirety of the second support overlaps the first support.

3. The printed circuit assembly of claim 1, wherein the first support comprises a first periphery defining an outer edge portion of the first support and a second periphery defining an inner edge of an opening overlapping the first circuit board.

4. The printed circuit assembly of claim 1, wherein the second circuit board comprises a connector positioned outside a first periphery of the first support.

5. The printed circuit assembly of claim 4, wherein the second support overlaps a 2nd-1 area of the second area of the first support, wherein the 2nd-1 area is adjacent to the connector.

6. The printed circuit assembly of claim 1, wherein the first circuit board and the second circuit board are connected to each other.

7. The printed circuit assembly of claim 1, wherein the first circuit board and the second circuit board are connected to each other and overlap each other outside a periphery of the first support and a periphery of the second support.

8. The printed circuit assembly of claim 1, wherein the first circuit board and the second circuit board are connected to each other, a first surface of the first circuit board is in contact with the first support and a first surface of the second circuit board, and a second surface of the second circuit board opposite to the first surface of the second circuit board is in contact with the first support.

9. The printed circuit assembly of claim 1, wherein the first support has a projecting portion in the second area and the second support overlaps the projecting portion of the first support in the second area.

10. The printed circuit assembly of claim 9, wherein the second circuit board comprises a connector extending from the projecting portion and positioned outside a first periphery of the first support.

11. The printed circuit assembly of claim 9, wherein the second support supports the projecting portion of the first support in the second area.

12. A method of manufacturing an electronic apparatus, the method comprising:
preparing a display apparatus; and
attaching the display apparatus to a housing;
wherein preparing the display apparatus comprises:
forming a printed circuit assembly, wherein forming the printed circuit assembly comprises:
providing a first support and a second support overlapping a first area of the first support and a second area of the first support;
positioning a first circuit board overlapping the first area of the first support and attached to a first surface of the first support; and
positioning a second circuit board overlapping the second area of the first support and attached to the first surface of the first support;
picking up the printed circuit assembly; and
attaching the printed circuit assembly to a display substrate,
wherein the second support is attached to a second surface of the first support opposite the first surface of the first support.

13. The method of claim 12, wherein an area of the second support is smaller than an area of the first support, and an entirety of the second support overlaps the first support, wherein picking up the printed circuit assembly comprises coupling a picker to the second support.

14. The method of claim 12, wherein the first support comprises a first periphery defining an outer edge portion of the first support and a second periphery defining an inner edge of an opening overlapping the first circuit board, wherein picking up the printed circuit assembly comprises coupling a picker to a portion of the second support adjacent to the opening.

15. The method of claim 12, wherein the second circuit board comprises a connector positioned outside the first support.

16. The method of claim 15, further comprising positioning the second support to overlap a 2nd-1 area of the second area of the first support, wherein the 2nd-1 area is adjacent to the connector.

17. The method of claim 12, further comprising bonding the first circuit board and the second circuit board together.

18. The method of claim 17, further comprising positioning the first circuit board and the second circuit board to overlap each other outside the first support and the second support.

19. The method of claim 17, further comprising positioning the first circuit board and the second circuit board such that a first surface of the first circuit board is in contact with the first support and a first surface of the second circuit board, and a second surface of the second circuit board opposite to the first surface of the second circuit board is in contact with the first support.

20. The method of claim 12, wherein the picking up comprises coupling a picker to the second support in the first area.

21. The method of claim 12, wherein the attaching comprises positioning the first circuit board and the second circuit board to face the display substrate.

22. The method of claim 12, further comprising separating the first support from the first circuit board and the second circuit board, wherein the first circuit board and the second circuit board remain attached to the display substrate.

23. The method of claim 12, further comprising bending a portion of the second circuit board.
